(19) United States
(12) Patent Application Publication
(10) Pub. No.: US 2005/0067005 A1
(43) Pub. Date: Mar. 31, 2005

(54) Thermoacoustic electric power generation

(76) Inventor: Alexander Michael Van Der Spek, GD Rijswijk (NL)

Correspondence Address: Del S Christensen;Shell Oil Company, Intellectual Property, P O Box 2463, Houston, TX, 77252-2463, US

(21) Appl. No.: 10/496,390

(22) PCT Filed: Nov. 26, 2002
(86) PCT No.: PCT/EP02/13315

(30) Foreign Application Priority Data
Nov. 26, 2001 (AU) PR6042

(51) Int. Cl. H01L 35/30

(52) U.S. Cl. 136/205

(57) ABSTRACT

A thermoacoustic power generator for generating electricity within or in the vicinity of a gas transportation conduit, such as a production tubing in a gas production well, having an acoustic resonance cavity having an inlet formed by an orifice in the wall of the conduit or of equipment arranged within the conduit to create a standing acoustic wave in the resonance cavity in response to the gas flow in the conduit, and a permeable body in the resonance cavity in which body cold and/or hot spots are formed as a result of adiabatic expansion or compression. A thermoelectric device, such as a Peltier element, is connected to the cold and/or hot spots formed in the permeable body to generate electrical power in response to the resulting temperature decrease or increase of the permeable body, which may exceed 50° C.

The invention relates to an electric power generator and a method for generating electric power within or in the vicinity of a gas transportation conduit.

Gas transportation conduits may be located at remote locations, such as downhole in a gas production well or underwater and/or underground, or in areas without a secure electric power supply, such as offshore or in unpopulated areas.

It is known from U.S. Pat. No. 6,150,601 to generate electricity in a gas production tubing downhole in a well by a thermoelectric device which is powered by a temperature gradient of the well, which gradient may be created by arranging a flow restriction in the production tubing in which the gas is expanded and cooled by adiabatic expansion. A disadvantage of the known system is that a flow restriction will reduce the amount of gas produced and that the gas is cooled off only a few degrees Celsius unless the flow restriction is large and very high, e.g. ultrasonic, gas velocities are reached in a venturi, in which case the venturi will create a large flow restriction and be subject to a high wear rate.

U.S. Pat. No. 6,011,346 discloses another downhole power generator, which comprises piezoelectric member, which is deformed by a pressure differential in a venturi. A disadvantage of this known power generator is that piezoelectric members have a low power output so that its efficiency is low.

It is an object of the present invention to alleviate the disadvantages of the known power generating systems and to provide a thermoacoustic power generator which has a higher efficiency than the known generators and which does not require the use of a flow restriction in the transportation conduit.

### SUMMARY OF THE INVENTION

The method according to the invention comprises:

inducing a gas that flows through the gas transportation conduit to flow along an inlet of an acoustic resonance cavity thereby creating a standing acoustic wave in the resonance cavity, inducing the fluid in the cavity to flow through a permeable body in which a number of substantially stationary cold spots and/or hot spots are formed as a result of adiabatic expansion or comprising of the resonating fluid; and

thermally connecting a thermoelectric device to at least one of said cold spots and/or hot spots to generate electrical power.

The permeable body may comprise a series of stacked plates, which are spaced at predetermined spacings from each other.

It is observed that U.S. Pat. Nos. 4,625,517 and 5,456,082 disclose thermoacoustic devices with permeable bodies formed by an array of rods or plates that may be used in the method and generator according to the invention.

The thermoelectric device may comprise a thermocouple, which may form part of a Peltier element.

Furthermore an array of acoustic signal transducers may be arranged in or adjacent to the gas transportation conduit, which transducers detect characteristics of a standing acoustic wave in the gas transportation conduit emitted from the inlet of the acoustic resonance device. The acoustic transducers may be microphones which convert phase differences of the acoustic signal at different distances from said inlet into an electric, fibre optical or other signal, that is transmitted to a flow monitoring system which converts the measured phase difference(s) and/or other characteristics of the acoustic signal(s) into an indication of the gas flow velocity in the gas transportation conduit.

Suitably, the microphones are powered by the electricity generated by the thermoelectric device and transform the acoustic signal into a pulsed digital acoustical, optical, electrical or other signal. The flow monitoring system may be connected to a flow control assembly, which adjusts the gas flow rate in the transportation conduit in response to deviation of the monitored gas velocity from a reference value.

The invention also relates to a thermoelectric power generator for generating electrical power within or in the vicinity of a gas transportation conduit. The power generator according to the invention comprises an acoustic resonance cavity having an inlet which is connectable to an opening in the wall of a gas transportation conduit or of equipment, such as a robotic device, logging tool or inspection and/or cleaning tool arranged within the conduit, a permeable body in the acoustic resonance tube which is in use at least partly cooled off or heated as a result of adiabatic expansion or compression of the resonating fluid and a thermoelectric device which is connectable to at least one cold spot and/or hot spot formed in use in the permeable body for generating electrical power.

### DESCRIPTION OF A PREFERRED EMBODIMENT

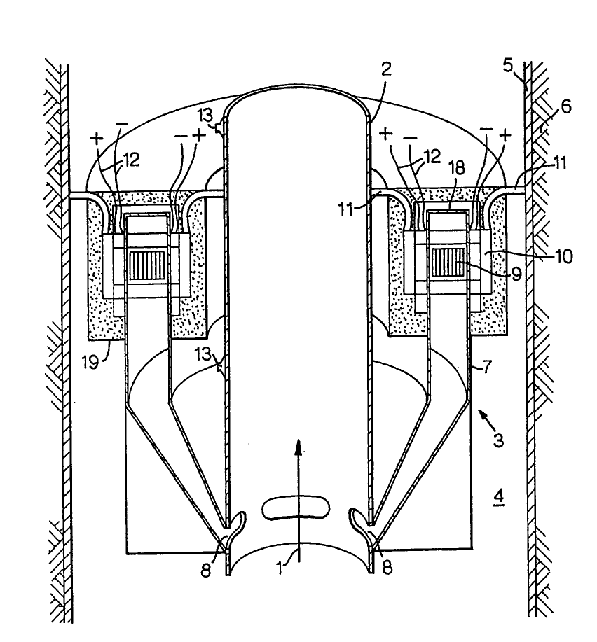

The invention will be described in more detail with reference to FIG. 1, which depicts a schematic longitudinal sectional view of a production tubing in a gas well which is equipped with a thermoacoustic power generator according to the invention.

In FIG. 1 a stream of natural gas 1 flows up through a production tubing 2 to a wellhead (not shown) at the earth surface. A thermoacoustic electric power generator 3 is arranged in the annular space 4 between the production tubing 2 and a well casing 5, which is cemented in an underground formation 6.

The power generator 3 comprises an annular acoustic resonance cavity 7, which has one or more inlet openings 8 which are formed by orifices or rings in the wall of the production tubing 2. The annular resonance cavity 7 has a closed top 18 and a permeable body 9 is mounted within the resonance tube 7 near the top 18.

An annular thermoelectric converter 10 is mounted adjacent to the permeable body 9. The converter 10 is formed by a Peltier element 11 comprising bimetallic or semiconductor electrocouples which generate electric power as a result of the temperature difference between permeable body 9 and other components of the well caused by the cooling of the permeable body as a result of adiabatic expansion of the gas in the resonance cavity 7 caused by the resonating acoustic wave in the cavity 7. The heat sink of the permeable body 9 may be more than 50° C. The cooled side of the Peltier element 10 is thus exposed to the heat sink of the permeable body and the other, hot, side of the Peltier element may be equipped with thermal conductors 11 which create a thermal bridge with adjacent uncooled components such as the wall of the production tubing 2 and the well casing 5. The upper end of the acoustic resonance cavity 7 and Peltier element 10 are encased in a protective and thermally insulating envelope 19.

The electrical cables 12 extend through the envelope 19 and are connected to a power conditioner and/or rechargeable battery and/or electrically powered downhole equipment (not shown), such as a gas flow monitoring and/or control system.

Suitably an array of microphones 13 is arranged in the production tubing 2 to detect the frequency and phase of the acoustic wave in the production tubing 2, which phase is related to the velocity of the gas stream 1 in the production tubing 2. Thus the signal generated by the microphones 13 may be transmitted to a flow monitoring device which converts the detected frequency into a gas velocity indication. The flow monitoring device may be located at the earth surface and the signal generated by the microphone may be transmitted to surface by an electric or fibre optical cable or as an amplified acoustic signal or as an electromagnetic signal which is transmitted via the wall of the production tubing 2.

It will be understood that the thermoacoustic power generator 3 may also be applied in conjunction with gas transportation conduits at or near the earth surface, such as subsea gas transportation pipelines and pipelines in remote areas, such as polar regions and deserts where there is no adequate electrical power supply to provide electrical power to necessary flow monitoring and control equipment.

Furthermore the thermoacoustic power generator according to the invention may be used to provide electrical power to equipment which is used within a gas transportation conduit or well, such as a robotic device, a well logging tool or an internal pipe inspection and/or cleaning tool. In such case the acoustic resonance cavity may be formed within the equipment housing and the inlet of the cavity is formed by one or more openings formed in the wall of the equipment housing, whereas a gas stream flows around the housing and initiates a standing acoustic wave within the acoustic resonance cavity.

In an alternative embodiment the thermoacoustic power generator according to the invention may operate as a heat pump and may be connected to a hot spot formed in the permeable body as a result of an adiabatic compression of the fluid resulting from the resonating acoustic wave pattern within the acoustic resonance cavity. The thermoelectric device may be coupled between one or more cold spots and one or more hot spots formed the permeable body as a result of the thermal effects resulting from the resonating acoustic wave pattern.

1. A method of generating power within or in the vicinity of a gas transportation conduit, the method comprising:
inducing a gas that flows through the gas transportation conduit to flow along an inlet of an acoustic resonance cavity thereby creating a standing acoustic wave in the resonance cavity, inducing the fluid in the cavity to flow through a permeable body in which a number of substantially stationary cold spots and/or hot spots are formed as a result of adiabatic expansion or compression of the resonating fluid; and
thermally connecting a thermoelectric device to at least one of said cold spots and/or hot spots to generate electrical power.

2. The method of claim 1, wherein the resonance cavity has an annular shape and is arranged downhole around a production tubing in a gas production well.

3. The method of claim 1, wherein the gas transportation conduit is a gas transport pipeline at a remote location, such as underwater and/or underground or in an area without electric power supply facilities.

4. The method of claim 1, wherein the permeable body comprises a series of stacked plates, which are spaced at predetermined spacings from each other.

5. The method of claim 2, wherein the stacked plates are formed in the annular resonance cavity by coiling a strip around the inner wall of the annular resonance tube and by arranging a series of spacers between the adjacent layers of the coiled strip.

6. The method of claim 1, wherein the thermoelectric device comprises a thermocouple which is connected between a hot spot and a cold spot of the permeable body or between a hot or cold spot of the permeable body and a component of which the temperature is substantially unaffected by the standing acoustic waves.

7. The method of claim 6, wherein the thermocouple forms part of a Peltier element.

8. The method of claim 1, wherein an array of acoustic signal transducers is arranged in or adjacent to the gas transportation conduit, which transducers detect characteristics of an acoustic wave in the gas transportation conduit emitted from the inlet of the acoustic resonance cavity.

9. The method of claim 8, wherein the acoustic transducers comprises microphones which converts the acoustic signal into an electric, fibre optical or other signal, which is transmitted to a flow monitoring assembly which converts phase differences and/or other characteristics of the acoustic signals into an indication of the gas flow velocity in the gas transportation conduit.

10. The method of claim 9, wherein the microphones are powered by the electricity generated by the thermoelectric cavity and transforms the acoustic signal into a pulsed digital acoustical, optical, electrical or other signal.

11. The method of claim 8, wherein the signal transducers comprises one or more rechargeable batteries, which are charged by the thermoelectric device.

12. The method of claim 9, wherein the flow monitoring system is connected to a flow control assembly which adjusts the gas flow rate in the transportation conduit in response to deviation of the monitored gas velocity from a reference value.

13. A thermoelectric power generator for generating electrical power within or in the vicinity of a gas transportation conduit, comprising:
an acoustic resonance cavity having an inlet which is connectable to an opening in the wall of a gas transportation conduit or of equipment arranged within the conduit;
a permeable body in the acoustic resonance tube which is in use at least partly cooled off or heated as a result of adiabatic expansion or compression of the resonating fluid; and
a thermoelectric device which is connectable to at least one cold spot and/or hot spot formed in use in the permeable body for generating electrical power.

14. The method of claim 2, wherein the permeable body comprises a series of stacked plates, which are spaced at predetermined spacings from each other.

15. The method of claim 3, wherein the permeable body comprises a series of stacked plates, which are spaced at predetermined spacings from each other.

16. The method of claim 4, wherein the stacked plates are formed in the annular resonance cavity by coiling a strip around the inner wall of the annular resonance tube and by arranging a series of spacers between the adjacent layers of the coiled strip.

17. The method of claim 2, wherein the thermoelectric device comprises a thermocouple which is connected between a hot spot and a cold spot of the permeable body or between a hot or cold spot of the permeable body and a component of which the temperature is substantially unaffected by the standing acoustic waves.

18. The method of claim 3, wherein the thermoelectric device comprises a thermocouple which is connected between a hot spot and a cold spot of the permeable body or between a hot or cold spot of the permeable body and a component of which the temperature is substantially unaffected by the standing acoustic waves.

19. The method of claim 4, wherein the thermoelectric device comprises a thermocouple which is connected between a hot spot and a cold spot of the permeable body or between a hot or cold spot of the permeable body and a component of which the temperature is substantially unaffected by the standing acoustic waves.

20. The method of claim 5, wherein the thermoelectric device comprises a thermocouple which is connected between a hot spot and a cold spot of the permeable body or between a hot or cold spot of the permeable body and a component of which the temperature is substantially unaffected by the standing acoustic waves.
